(19) United States
(12) Patent Application Publication
(10) Pub. No.: US 2024/0363485 A1
(43) Pub. Date: Oct. 31, 2024

(54) ELECTRONIC ASSEMBLIES WITH INTERPOSER ASSEMBLY

(71) Applicant: Tesla, Inc., Austin, TX (US)

(72) Inventor: Yong guo Li, Gilroy, CA (US)

(21) Appl. No.: 18/683,335

(22) PCT Filed: Aug. 9, 2022
(86) PCT No.: PCT/US2022/039862

§ 371 Date: Feb. 13, 2024

Related U.S. Application Data
(60) Provisional application No. 63/260,388, filed on Aug. 18, 2021.

(51) Int. Cl. H01L 23/40

(52) U.S. Cl. CPC H01L 23/4006; H01L 2023/4087

(57) ABSTRACT

A system on a wafer (SoW) assembly is disclosed. The SoW assembly can include a cooling component, and a frame structure that is coupled to the cooling component by way of at least one fastener. The SoW assembly can include an interposer assembly that is disposed on a SoW. At least a portion of the interposer assembly can be disposed between the cooling component and the frame structure. The SoW assembly can include a gasket disposed between the portion of the interposer assembly and the frame structure.

### CROSS-REFERENCE TO RELATED APPLICATION

This application claims the benefit of U.S. Provisional Patent Application No. 63/260,388, titled “ELECTRONIC ASSEMBLIES AND METHODS OF MANUFACTURING THE SAME,” filed Aug. 18, 2021, the disclosure of which is incorporated herein by reference in its entirety and for all purposes.

### TECHNICAL FIELD

The present disclosure relates generally to electronic assemblies and methods of manufacturing the same.

### BACKGROUND

A system on a wafer (SoW) assembly can include a SoW and a heat dissipation structure coupled to the SoW. When the SoW and the heat dissipation structure are bonded together, a significant pressure can be applied. Significant force can be applied to a SoW assembly during manufacturing. Such force can be applied unevenly to the SoW.

### SUMMARY OF CERTAIN INVENTIVE ASPECTS

In one aspect, a system on a wafer (SoW) assembly is disclosed. The SoW assembly can include a cooling component, a frame structure that is coupled to the cooling component by way of at least one fastener, and an interposer assembly that is disposed on a SoW. At least a portion of the interposer assembly is disposed between the cooling component and the frame structure. The SoW assembly can include a gasket that is disposed between the portion of the interposer assembly and the frame structure.

In one embodiment, the frame structure includes an inner frame portion, an outer frame portion, and an opening between the inner frame portion and the outer frame portion. The interposer assembly can include a carrier and a connector coupled to the carrier, the connector being accessible through the opening. The SoW assembly can further include voltage regulating modules (VRMs) disposed in an inner opening defined by the inner frame portion. The gasket can include an elongate structure positioned between the inner frame portion and the portion of the interposer assembly. The SoW assembly can further include a second gasket having a plurality of spaced islands. Each island of the islands of the second gasket is shorter than the elongate structure of the gasket.

In one embodiment, the SoW includes an array of integrated circuit dies, and the interposer assembly provides an input/output connector for the SoW assembly. The array of integrated circuit dies can be configured to perform neural network training.

In one embodiment, the SoW assembly further includes a plurality of additional interposer assemblies positioned around a periphery of the SoW. The interposer assembly and the plurality of additional interposer assemblies each includes an input/output connector for the SoW assembly.

In one embodiment, the gasket includes a compressible material. The gasket can further include a conductive layer at least partially around the compressible material. The gasket can further include a pressure sensitive adhesive on the conductive layer. The gasket can be configured to provide a ground path between the frame structure and the interposer assembly.

In one aspect, a system on a wafer (SoW) assembly is disclosed. The SoW assembly can include a frame structure that has a first opening at an edge region of the frame structure. The SoW assembly can include a cooling component that is coupled to the frame structure by way of at least one fastener. The SoW assembly can include an interposer assembly on a SoW with an array of integrated circuit dies. The interposer assembly includes a carrier and a connector that is coupled to the carrier. The connector is accessible through the first opening of the frame structure. A portion of the carrier is positioned between the frame structure and the cooling component. The SoW assembly can include a gasket that is disposed between the portion of the carrier and the frame structure.

In one embodiment, the frame structure further has a second opening at a center region of the frame structure. The SoW assembly can further include voltage regulating modules (VRMs) that are disposed in the second opening of the frame structure.

In one embodiment, the gasket includes a compressible material. The gasket can further include a conductive layer at least partially around the compressible material. The gasket can further include a pressure sensitive adhesive.

In one embodiment, the interposer assembly provides an input/output connector for the SoW assembly.

### BRIEF DESCRIPTION OF THE DRAWINGS

Specific implementations will now be described with reference to the following drawings, which are provided by way of example, and not limitation.

FIG. 1 shows a schematic cross sectional side view of a processing system.

FIG. 2 is a schematic perspective view of a portion of a processing system according to an embodiment.

FIG. 3 is a schematic perspective view of an interposer assembly.

FIG. 4 is a top plan view showing a plurality of the interposer assemblies disposed over a system on a wafer (SoW).

FIG. 5A is a schematic perspective first view of a frame structure.

FIG. 5B is a schematic perspective second view of the frame structure.

FIG. 5C is a plan view of the frame structure.

FIG. 6 is a schematic perspective view of the gasket.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals and/or terms can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

System on a wafer (SoW) assemblies can include a SoW and a cooling system that is coupled to the SoW. The SoW can include an array of integrated circuit dies. The SoW can be sensitive to an external force. The SoW and the cooling component can include an array of electronic modules, such as voltage regulating modules (VRMs), positioned therebetween. A thermal interface material (TIM) can be positioned between the VRMs and the cooling component.

In SoW assemblies, there are technical challenges related to controlling clamping of an interposer to a cooling component. There can be multiple forces from springs, connector insertion, cable pulling, etc. A technical solution that can control clamping under application of significant force is desired.

For the cooling component to sufficiently and/or desirably dissipate heat generated by various components of the SoW assembly, it can be preferred to apply force to the heat generating components against the cooling component evenly or uniformly. Various embodiments disclosed herein relate to a coupling feature that enables minimizing or eliminating variations of the force applied to the heat generating components. For example, gaskets with a compressible material can be provided to absorb variations in force.

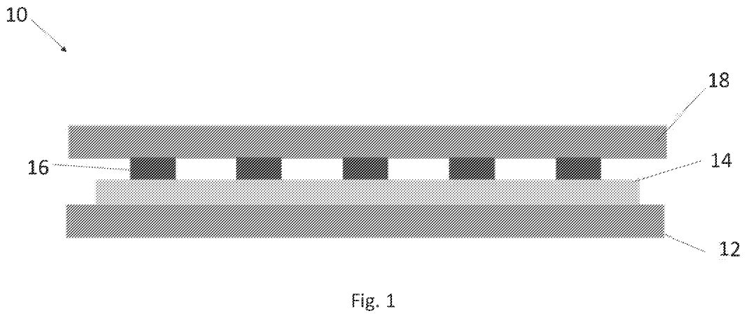

FIG. 1 shows a schematic cross sectional side view of a processing system 10. The processing system can comprise a system on a wafer (SoW) assembly. The processing system 10 can have a high compute density and can dissipate heat generated by the processing system 10. The processing system 10 can execute trillions of operations per second in certain applications. The processing system 10 can be used in and/or specifically configured for high performance computing and/or computation intensive applications, such as neural network training and/or processing, machine learning, artificial intelligence, or the like. The processing system 10 can implement redundancy. In some applications, the processing system 10 can be used to generate data for an autopilot system of a vehicle (e.g., an automobile) or the like.

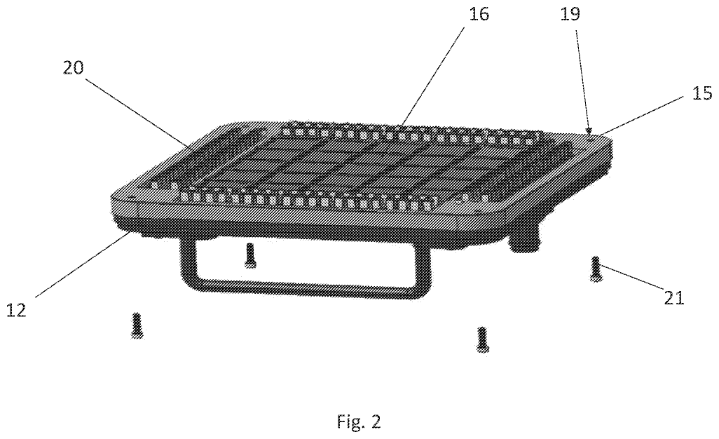

FIG. 2 is a schematic perspective view of a portion of a processing system 10 according to an embodiment. The processing system 10 shown in FIG. 2 can share various components of the processing system 10 illustrated in FIG. 1.

As illustrated in FIG. 1, the processing system 10 includes a cooling component 12, a SoW 14, voltage regulating modules (VRMs) 16, and a cooling system 18. As illustrated in FIG. 2, the processing system 10 includes a cooling component 12, a frame structure 15, voltage regulating modules (VRMs) 16, and interposer assemblies 20. The cooling component 12 and the SoW 14 can be vertically stacked using a coupling structure that can comprise the frame structure 15 with one or more gaskets.

The cooling component 12 can cool the SoW 14. The cooling component 12 can be any suitable component to dissipate heat, remove heat, or otherwise reduce temperature of components of a processing system during operation. The cooling component 12 can include a heat spreader. Such a heat spreader can include a metal plate. Alternatively or additionally, the cooling component 12 can include a heat sink. The cooling component 12 can include any suitable material with desirable heat dissipation properties. In some instances, the cooling component 12 can include a cold plate arranged to have coolant flow therethrough for active cooling. A thermal interface material can be included between the cooling component 12 and the SoW 14 to reduce and/or minimize heat transfer resistance.

The SoW 14 can include an array of integrated circuit (IC) dies. The IC dies can be embedded in a molding material. The SoW 14 can have a high compute density. The IC dies can be semiconductor dies, such as silicon dies. The array of IC dies can include any suitable number of IC dies. For example, the array of IC dies can include 16 IC dies, 25 IC dies, 36 IC dies, or 49 IC dies. The SoW 14 can be an Integrated Fan-Out (InFO) wafer, for example. InFO wafers can include a plurality of routing layers over an array of IC dies. For example, an InFO wafer can include 4, 5, 6, 8, or 10 routing layers in certain applications. The routing layers of the InFO wafer can provide signal connectivity between the ICs dies and/or to external components. The SoW 14 can have a relatively large diameter, such as a diameter in a range from 10 inches to 15 inches. As one example, the SoW 14 can have a 12 inch diameter.

The frame structure 15 can contribute to the structural integrity of the processing system 10. The edge stiffener 15 can provide support to the VRMs 16 and keep the VRMs 16 in place.

The VRMs 16 can be positioned such that each VRM is stacked with an IC die of the SoW 14. In the processing system 10, there is high density packing of the VRMs 16. Accordingly, the VRMs 16 can consume significant power. The VRMs 16 are configured to receive a direct current (DC) supply voltage and supply a lower output voltage to a corresponding IC die of the SoW 14.

The cooling system 18 can provide active cooling for the VRMs 16. The cooling system 18 can include metal with flow paths for heat transfer fluid to flow through. In the assembled processing system 10, the cooling system 18 can be bolted to the cooling component 12. This can provide structural support for the SoW 14 and/or can reduce the chance of the SoW 14 breaking.

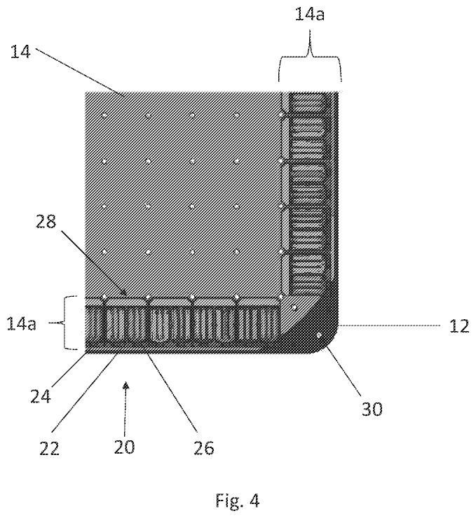

The cooling component 12 can be coupled with the frame structure 15 by way of at least one fastener, such as one or more screws 21. The screws 21 can be provided through respective holes 30 (see FIG. 4) of the cooling component 12 and respective holes 19 of the frame structure 15 to couple the cooling component 12 with the frame structure 15.

The cooling component 12 and/or the frame structure 15 can comprise an alignment structure for horizontally aligning the position of the cooling component 12 relative to the frame structure 15.

The interposer assemblies 20 can be positioned at edge regions of the processing system 10. In some embodiments, one or more arrays of the interposer assemblies 20 can be positioned laterally around the VRMs 16. For example, at each side of the processing system 10, interposer assemblies 20 each having two connectors can be positioned laterally around the VRMs 16. The interposer assemblies 20 can have input/output connectors accessible thought openings of the frame structure 15. As illustrated, a relatively high density of connectors can be achieved with the interposer assemblies 20. The interposer assembly 20 can provide interface routing between the processing system 10 and another processing system or an external device.

A method of manufacturing the processing system 10 can include providing a SoW 14, and a cooling component 12, coupling the SoW 14 and the interposer assemblies with the cooling component 12 by way of a frame structure 15 and one or more fasteners 21. Coupling the SoW 14 and the interposer assemblies 20 with the cooling component 12 can include positioning connectors of the interposer assemblies 20 in openings of the frame structure 15, and positioning at least an area of a carrier of the interposer assemblies 20 between a portion of the frame structure 15 and the cooling component 12.

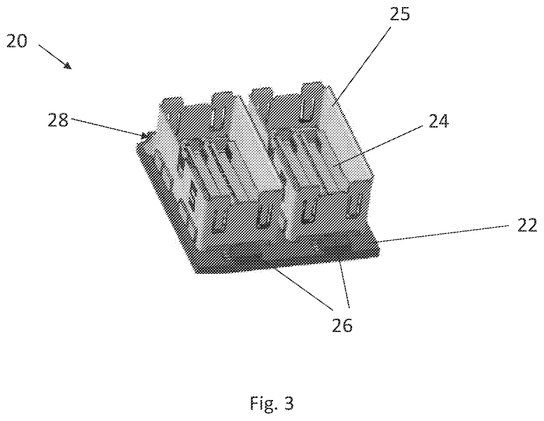

FIG. 3 is a schematic perspective view of an interposer assembly 20. The interposer assembly 20 can include a carrier 22, one or more connectors 24 coupled to the carrier 22, and one or more surface mount components 26 mounted on the carrier 22. The interposer assembly 20 can include a connector housing 25. In some embodiments, the connector 24 can comprise a female connector, and the connector housing 25 can configure to guide a male connector (not shown) to connect to the connector 24. The interposer assembly 20 can provide interfacing routing between the processing system 10 and another processing system or an external device. For example, an array of processing systems 10 can be connected to each other via interposer assemblies 20. In some embodiments, the connectors 24 can comprise high speed connectors that are configured as input/output connectors for the processing system 10. Such connectors can have high throughput. In some instances, connectors 24 can carry a differential pair of signals. The one or more surface mount components 26 can include, for example, a surface mount capacitor, a surface mount inductor, or a surface mount capacitor and a surface mount inductor. The carrier 22 can comprise an interposer printed circuit board (PCB). The carrier 22 can have an area 28 that is configured to receive force applied to the carrier 22. The area 28 of the carrier 22 can be free from electronic components.

FIG. 4 is a top plan view showing a plurality of the interposer assemblies 20 disposed over the SoW 14. The SoW is disposed on the cooling component 12. The interposer assemblies 20 can be positions at or near edge regions 14a of the SoW 14. Accordingly, the interposer assemblies 20 can be positioned along a periphery or perimeter of the SoW 14. The SoW 14 can include integrated circuit dies (not shown) underneath the interposer assemblies 20. Pressure in a particular range can be applied to the integrated circuit dies for achieving sufficient thermal performance, for example, as described below.

The cooling component 12 can include an alignment hole 30. In some embodiments, the cooling component 12 can include the alignment hole 30 at each corner of the cooling component 12.

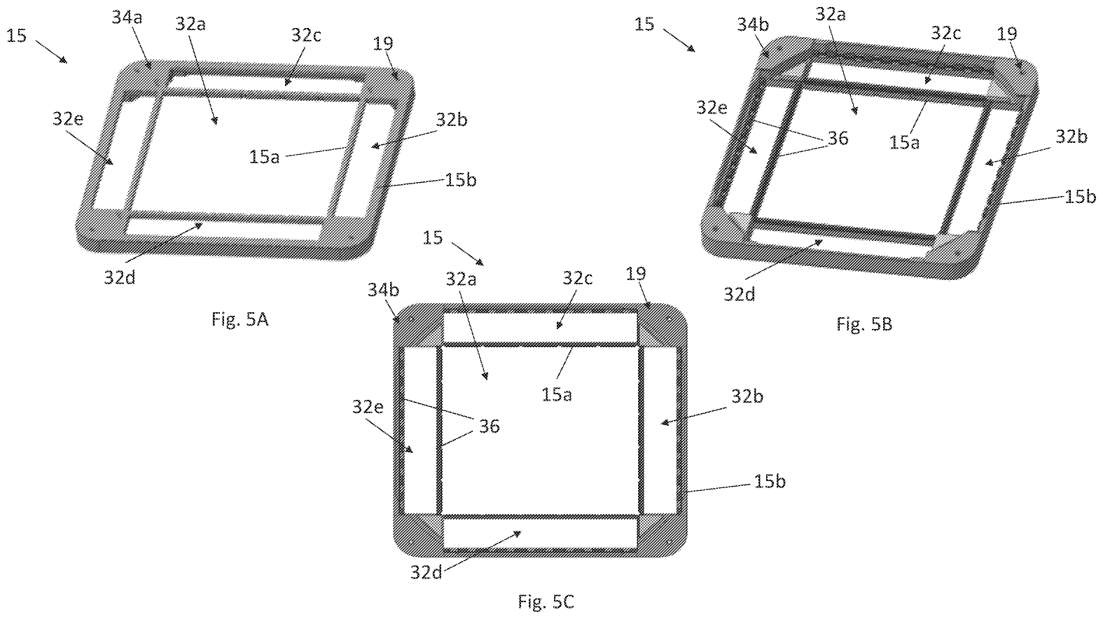

FIG. 5A-5C show various views of the frame structure 15. FIG. 5A is a schematic perspective first view of the frame structure 15. FIG. 5B is a schematic perspective second view of the frame structure 15. FIG. 5C is a plan view of the frame structure 15. The frame structure 15 can comprise an inner frame portion 15a and an outer frame portion 15b. The frame structure 15 can have openings 32a, 32b, 32c, 32d, 32e. In some embodiments, the frame structure 15 can have the opening 32a at a center region of the frame structure 15 and the openings 32b, 32c, 32d, 32e at edge regions of the frame structure 15. In some embodiments, the first opening 32a can be defined by the inner frame portion 15a, and the openings 32b, 32c, 32d, 32e can be defined by the space between the inner frame portion 15a and the outer frame portion 15b. The opening 32a can be configured to receive the VRMs 16 and the openings 32b, 32c, 32d, 32e can be configured to receive the connectors 24 of the interposer assemblies 20, for example, as shown in FIG. 2. The connectors 24 can be accessible through the openings 32b, 32c, 32d, 32e. The connectors 24 can function as input/output connectors of a processing system. In such instances, the frame 15 can be referred to as an input/output frame. The frame structure 15 has a first side 34a and a second side 34b opposite the first side 34a. Gaskets 36 can be positioned on portions of the second side 34b of the frame structure 34b. Some portions of the second side 34b of the frame structure 34b can be free from the gaskets 36.

The inner frame portion 15a can be relatively thin such that pressure applied by the fasteners 21 (see FIG. 2) to the inner frame portion 15a can result in a relatively small deformation or deflection of the inner frame portion 15a. The deformed or deflected inner frame portion 15a can contribute to applying non-uniform or uneven force to the area 28 of the carrier 22 of interposer assemblies 20 (see FIG. 3). Such non-uniform or uneven force applied to the interposer assemblies 20 may not be desired.

The gaskets 36 can comprise a compressible material to compensate for and/or reduce the impact of the non-uniform or uneven force applied to the interposer assemblies 20. The gaskets 36 can control a gap between the frame structure 15 and the cooling component 12, which can in turn control a total deflection of thin areas of the frame structure 15 when compression force is applied to the frame structure 15. The gaskets 36 can absorb the non-uniform or uneven force applied to the interposer assemblies within a tolerance variation. The gaskets 36 can be arranged so as to absorb most or all force applied to the inner frame portion 15a. More evenly distributed compression force to the areas 28 of the plurality of interposer assemblies 20 can enable improved thermal performance in the processing system 10.

In some embodiments, the gaskets 36 at different locations can comprise different structures and/or different compositions. For example, the gaskets 36 on the inner frame portion 15a can comprise different structure from the gaskets 36 on the outer frame portion 15b. In some embodiments, the gaskets 36 on the outer frame portion 15b can consist or consist essentially of a compressible material, such as polyurethane (PU). Such gaskets 36 can serve primarily or only for compression purposes. The gasket 36 on the inner frame portion 15a can serve a grounding function in addition to reducing the impact of force on the SoW. Such gaskets 36 can include an electrically conductive material around a compressible material. In some embodiments, the gasket 36 on the inner frame portion 15a can have an elongate structure, and the gasket 36 on the outer portion 15b can have a plurality of spaced islands each of which has shorter length than the elongate structure.

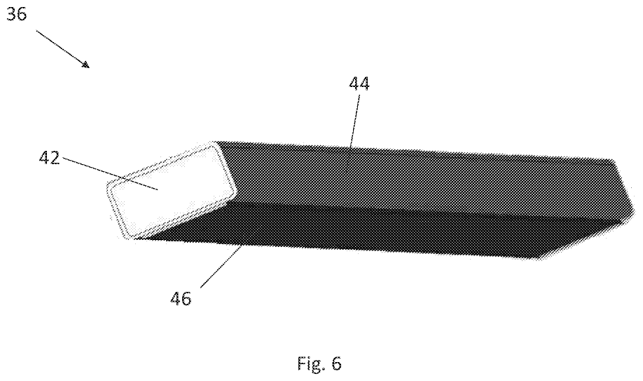

FIG. 6 is a schematic perspective view of a gasket 36 that can be on inner frame portion 15a. The gasket 36 can comprise a compressible material 42, a conductive layer 44, and an adhesive 46. For example, the compressible material 42 can comprise polyurethane (PU). For example, the conductive layer 44 can comprise a conductive fiber layer. For example, the adhesive 46 can comprise a pressure sensitive adhesive (PSA). In some embodiments, the gasket 36 can provide a ground path between the frame structure 15 and the interposer assembly 20.

Any suitable principles and advantages disclosed herein can be applicable to wafer level packaging and/or high density multiple die packaging. Though the embodiments disclosed herein used VRMs as an example, any suitable electrical module, component, die, chip, or the like may be mounted on a wafer and utilize any suitable principles and advantages disclosed herein. Any suitable combination of features of two or more embodiments disclosed herein can be implemented.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

The foregoing description has been described with reference to specific embodiments. However, the illustrative discussions above are not intended to be exhaustive or to limit the inventions to the precise forms described. Many modifications and variations are possible in view of the above teachings. Others skilled in the art are thereby enabled to best utilize the techniques and various embodiments with various modifications as suited to various uses.

Although the disclosure and examples have been described with reference to the accompanying drawings, various changes and modifications will become apparent to those skilled in the art. Such changes and modifications are to be understood as being included within the scope of the disclosure.

What is claimed is:

1. A system on a wafer (SoW) assembly comprising:
a cooling component;
a frame structure coupled to the cooling component by way of at least one fastener;
an interposer assembly disposed on a SoW, at least a portion of the interposer assembly disposed between the cooling component and the frame structure; and
a gasket disposed between the portion of the interposer assembly and the frame structure.

2. The SoW assembly of claim 1, wherein the frame structure comprising an inner frame portion, an outer frame portion, and an opening between the inner frame portion and the outer frame portion.

3. The SoW assembly of claim 2, wherein the interposer assembly comprises a carrier and a connector coupled to the carrier, the connector being accessible through the opening.

4. The SoW assembly of claim 3, further comprising voltage regulating modules (VRMs) disposed in an inner opening defined by the inner frame portion.

5. The SoW assembly of claim 2, wherein the gasket comprises an elongate structure positioned between the inner frame portion and the portion of the interposer assembly.

6. The SoW assembly of claim 5, further comprising a second gasket having a plurality of spaced islands, each island of the islands of the second gasket being shorter than the elongate structure of the gasket.

7. The SoW assembly of claim 1, wherein the SoW comprises an array of integrated circuit dies, and the interposer assembly provides an input/output connector for the SoW assembly.

8. The SoW assembly of claim 7, wherein the array of integrated circuit dies are configured to perform neural network training.

9. The SoW assembly of claim 1, further comprising a plurality of additional interposer assemblies positioned around a periphery of the SoW, the interposer assembly and the plurality of additional interposer assemblies each comprising an input/output connector for the SoW assembly.

10. The SoW assembly of claim 1, wherein the gasket comprises a compressible material.

11. The SoW assembly of claim 10, wherein the gasket further comprises a conductive layer at least partially around the compressible material.

12. The SoW assembly of claim 11, wherein the gasket further comprises a pressure sensitive adhesive on the conductive layer.

13. The SoW assembly of claim 11, wherein the gasket is configured to provide a ground path between the frame structure and the interposer assembly.

14. A system on a wafer (SoW) assembly comprising:
a frame structure having a first opening at an edge region of the frame structure;
a cooling component coupled to the frame structure by way of at least one fastener;
an interposer assembly on a SoW with an array of integrated circuit dies, the interposer assembly including a carrier and a connector coupled to the carrier, the connector accessible through the first opening of the frame structure, a portion of the carrier positioned between the frame structure and the cooling component; and
a gasket disposed between the portion of the carrier and the frame structure.

15. The SoW assembly of claim 14, wherein the frame structure further has a second opening at a center region of the frame structure.

16. The SoW assembly of claim 15, further comprising voltage regulating modules (VRMs) disposed in the second opening of the frame structure.

17. The SoW assembly of claim 14, wherein the gasket comprises a compressible material.

18. The SoW assembly of claim 17, wherein the gasket further comprises a conductive layer at least partially around the compressible material.

19. The SoW assembly of claim 18, wherein the gasket further comprises a pressure sensitive adhesive.

20. The SoW assembly of claim 14, wherein the interposer assembly provides an input/output connector for the SoW assembly.
